(19) United States
(12) Patent Application Publication
(10) Pub. No.: US 2004/0256672 A1
(43) Pub. Date: Dec. 23, 2004

(54) Ultra-small MOSFET

(75) Inventor: Hideaki Tsuchiya, Kobe-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Semiconductor Technology Academic Research Center, Yokohama-shi (JP)

(21) Appl. No.: 10/867,805

(22) Filed: Jun. 16, 2004

(30) Foreign Application Priority Data
Jun. 20, 2003 (JP) 2003-176917

(51) Int. Cl. H01L 29/76

(52) U.S. Cl. 257/346

(57) ABSTRACT

A new MOSFET structure capable of controlling short-channel effects in an ultra-small MOSFET, whose channel length is less than or equal to 10 nm, has been disclosed. The MOSFET comprises a channel region whose channel length is less than or equal to 10 nm, a source region and a drain region formed at both sides of the channel region, an insulating film provided so as to cover at least the channel region, and a gate electrode provided so as to face the channel region via the insulating film, wherein the length of the gate electrode is greater than the channel length and both ends of the gate electrode overlap the source region and the drain region via the insulating film.

### BACKGROUND OF THE INVENTION

The present invention relates to a MOSFET and, more particularly, to a MOSFET, having an ultra-small structure, whose channel length is 10 nm or less.

Recently, there is a growing demand for higher performance from an LSI. One of the factors essential for higher performance in an LSI is the higher performance of a transistor. Regarding the higher performance of a transistor, the method for reducing the dimensions of a transistor according to Moore's law, that is, the scaling law, is known and a higher performance has been achieved by the miniaturization of a transistor. The International Technology Roadmap for Semiconductors (ITRS) predicts that the miniaturization of a transistor will be accelerated more and more in the future. As for an ultra-small MOSFET whose element size is 70 nm or less, the limit to the miniaturization has surfaced in various fields of technology, and it is expected that an extension of the prior art will be insufficient and will bring about various problems.

When a MOSFET is miniaturized, it is necessary to control short-channel effects that lower a threshold as the channel length is reduced. Methods for controlling the short-channel effects include a method for increasing the concentration of impurities inside a substrate, a method for providing a halo region under a source-drain extension region, a method for introducing a silicon-on-insulator (SOI) technology, etc.

The characteristic of a MOSFET requires a high ratio of on-state current to off-state current.

### SUMMARY OF THE INVENTION

Among the methods for controlling the short-channel effects described above, the method for increasing the concentration of impurities inside a substrate will cause the tunnel current to increase at a source-drain junction or the channel mobility to lower if the concentration of impurities is made too high. If the tunnel current increases, the current during off-state is caused to increase and therefore, the ratio of on-state current to off-state current is lowered. Moreover, if the channel mobility lowers, the current during the on-state is caused to decrease and therefore, the ratio of on-state current to off-state current is lowered similarly. When the concentration of impurities is, for example, 1024 atoms/m³, the distribution interval between impurities is about 10 nm. Therefore, if the channel length becomes 10 nm or less, the number of impurity atoms distributed in the channel region becomes extremely small, therefore, it becomes very difficult to stably control the distribution of impurity atoms in the channel region during the manufacturing process and a problem arises that manufacturing becomes difficult.

Moreover, the method in which a halo region is provided under a source-drain extension suffers from problems in that the control of the distribution of impurities in the halo region becomes very difficult, for the same reason as described above, when the channel length becomes extremely small.

As described above, as for an ultra-small MOSFET whose channel length is 10 nm or less, the conventional method for controlling the short-channel effects by controlling the distribution of impurities in the channel region is reaching its technical limit and a new method for controlling the short-channel effects such as a method for improving the channel structure is required.

The present invention has been developed in order to satisfy the demand described above and the object thereof is to realize a new MOSFET structure capable of controlling the short-channel effects in an ultra-small MOSFET whose channel length is 10 nm or less.

In order to realize the above-mentioned object, a MOSFET of the present invention, which has a channel region whose channel length is 10 nm or less, is characterized in that the length of a gate electrode is made longer than the channel length so that the MOSFET has overlap regions at which both ends of the gate electrode overlap a source region and a drain region via an insulating film.

The inventors have developed a simulator adopting the quantum correction for performing a simulation of the above-mentioned structure and confirmed that the sub-threshold current is reduced and the ratio of on-state current to off-state current is increased.

The reason why the sub-threshold current is reduced and the ratio of on-state current to off-state current is increased in the ultra-small MOSFET of the present invention can be thought to be as follows.

In the ultra-small MOSFET, the quantization of carriers needs to be taken into account during the on-state. If the gate electrode is made to overlap the source region and the drain region, electrons change their state from the three-dimensional state into the two-dimensional state in the region where the channel and the source region overlap each other (the overlap region) during on-state and the degree of freedom is decreased, therefore, the density of state is reduced and the sheet density is reduced. Because of this, a neutral condition between donors and charges collapses and a state of excess donors (positive charges) is brought about. These excess positive charges lower the potential in the overlap region and the potential in the vicinity of the source end of the channel is also lowered. Therefore, the carrier injection from the source region becomes more likely to occur, enabling the concentration of the induced carriers in the channel to increase. As described above, it is possible to increase the drive current during on-state by providing the overlap region.

On the other hand, in the overlap region during the off-state, if the thickness of a SOI film is reduced extremely, the carrier depletion due to the gate voltage cannot be ignored and the effect that the channel length is effectively increased by the amount corresponding to the length of overlap is brought about. Due to this, it is possible to reduce the sub-threshold current because the drain current is controlled in the wide region (channel region+overlap region) covered by the gate electrode during off-state. As described above, it is possible to realize not only an increase in on-state current, but also an increase in the ratio of on-state current to off-state current, by providing the overlap region.

In order to control the short-channel effects, the thickness of the channel is also important and it is desirable that the thickness of the channel is equal to or less than the channel length.

It is desirable that the channel region, the source region and the drain region are formed on a silicon-on-insulator (SOI) film and the film thickness should be determined in accordance with the channel length, for example, if the channel length is 5 nm, it is desirable that the length of the overlap region is 2 to 3 nm.

It is desirable that the channel region is substantially a silicon layer that does not contain impurities because manufacturing thereof can be made easier.

It is desirable that the concentration of impurities in the source region and the drain region that overlap the gate electrode via an insulating film is equal to or higher than 10²⁰/cm³.

### BRIEF DESCRIPTION OF THE DRAWINGS

The features and advantages of the invention will be more clearly understood from the following description taken in conjunction with the accompanying drawings, in which:

FIG. 1 is a diagram showing a structure of a MOSFET in a first embodiment of the present invention.

FIG. 2A to FIG. 2F are diagrams showing the simulation results of the electron sheet density distribution in the MOSFET in the first embodiment.

FIG. 3A to FIG. 3F are diagrams showing the simulation results of the potential distribution in the MOSFET in the first embodiment.

FIG. 4A to FIG. 4F are diagrams showing the simulation results of the electron sheet density distribution in the MOSFET under another condition in the first embodiment.

FIG. 5A to FIG. 5F are diagrams showing the simulation results of the potential distribution in the MOSFET under another condition in the first embodiment.

FIG. 6 is a diagram showing the sub-threshold characteristic of the MOSFET in the first embodiment.

FIG. 7A and FIG. 7B are diagrams showing the sub-threshold characteristic of the MOSFET in the first embodiment.

FIG. 8A and FIG. 8B are diagrams showing a structure of a MOSFET in a second embodiment of the present invention.

FIG. 9A to FIG. 9D are diagrams showing a structure of a MOSFET in a third embodiment of the present invention.

### DESCRIPTION OF THE PREFERRED EMBODIMENTS

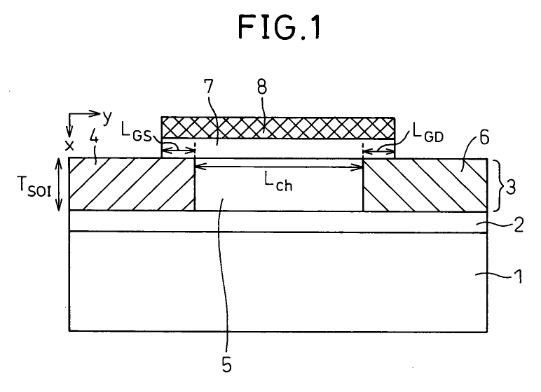

FIG. 1 is a diagram showing the structure of the MOSFET in the first embodiment of the present invention. As shown schematically, in the MOSFET in the first embodiment, a buried SiO₂ layer 2 is formed on a substrate 1 and a silicon-on-insulator (SOI) film 3 is formed thereon. Then, a source region 4 and a drain region 6 are formed at both sides of a channel region 5 of the SOI film 3. The channel region 5 is not doped with anything and the concentration of impurities in the source region 4 and the drain region 6 is 10²⁰/cm³. The thickness of the SOI film 3 is denoted by T_{SOI} and the length of the channel region 5 is denoted by L_{CH}. On the SOI film 3 on which the channel region 5, the source region 4 and the drain region 6 have been formed, a gate insulating film 7, which is a SiO₂ film, is formed and a gate electrode 8, which is an N-type polysilicon layer, is further formed thereon. The gate electrode 8 is longer than the length L_{CH} of the channel region 5 and both ends thereof overlap the source region 4 and the drain region 6. The lengths of the overlap region are L_{GS} and L_{GD}, respectively. In other words, the length of the gate 8 is L_{CH}+L_{GS}+L_{GD}. The length of the gate insulating film 7 is equal to the length of the gate electrode 8 and the gate insulating film 7 needs to be this length or longer. As described above, the MOSFET in the first embodiment is characterized in that the gate electrode 8 is longer than the channel length and overlaps the source region 4 and the drain region 6 via the gate insulating film 7.

In the case of the MOSFET in the first embodiment, it is possible to obtain a more excellent ratio of on-state current to off-state current compared to the case where the gate electrode 8 overlaps neither the source region 4 nor the drain region 6.

In the ultra-small MOSFET in the first embodiment, whose channel length is 10 nm or less, a conventionally used simulator cannot be used. Therefore, the inventors have developed a simulator adopting quantum correction and performed a simulation of the characteristics of the MOSFET having the structure shown in FIG. 1.

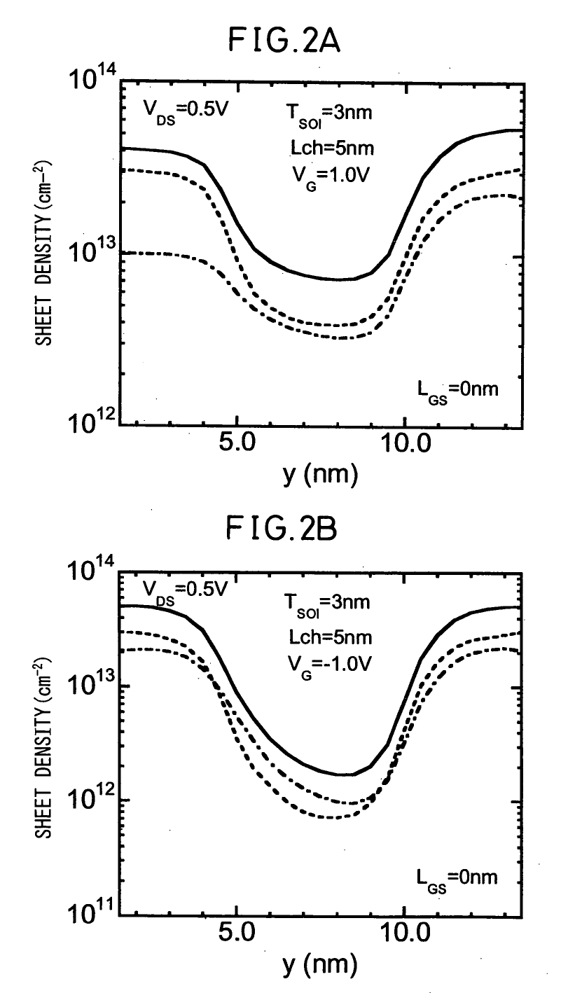

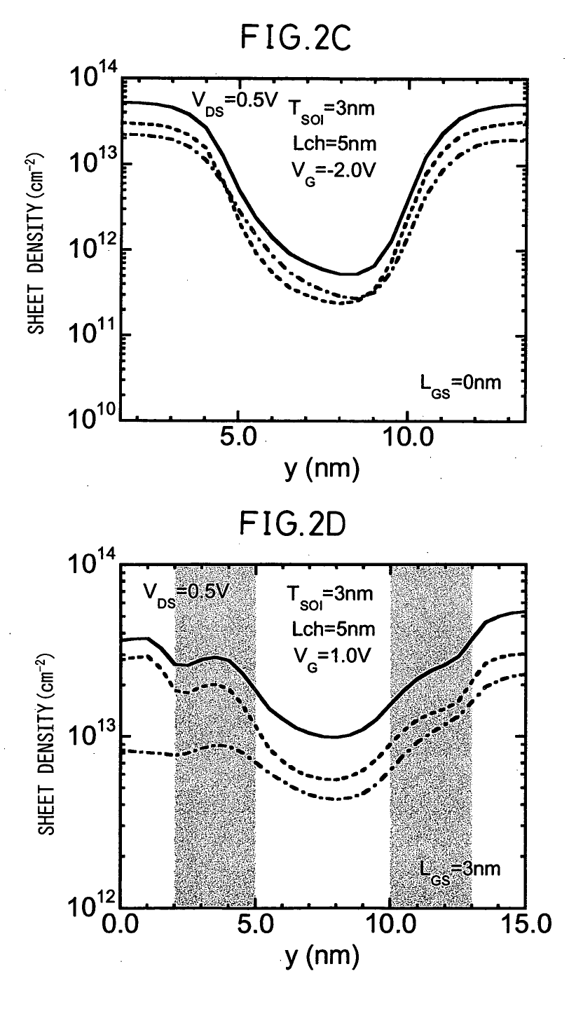

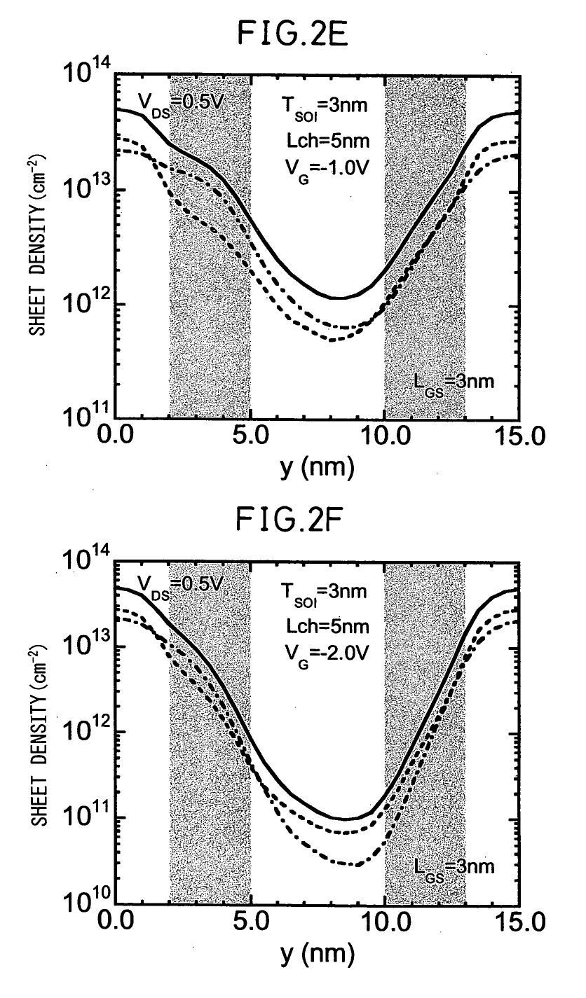

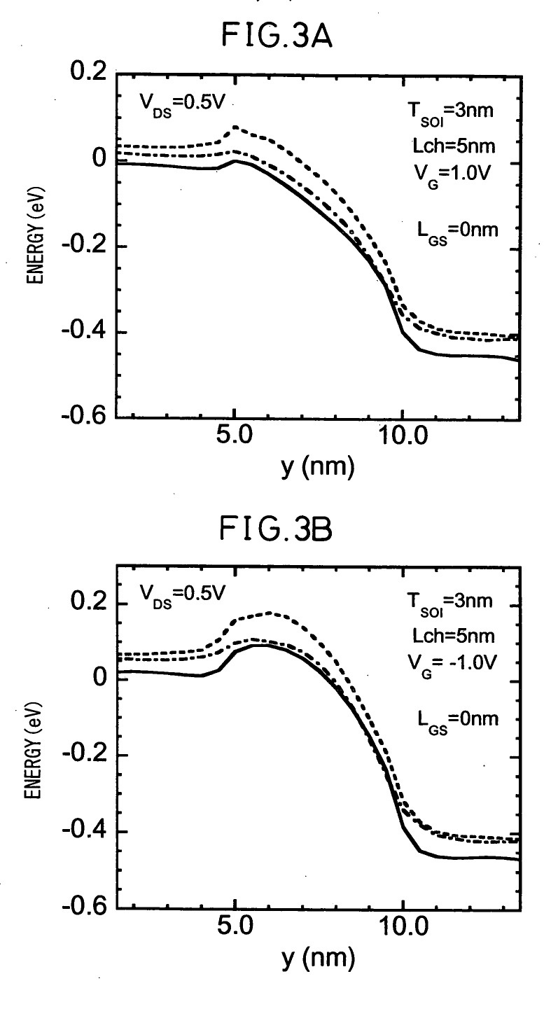

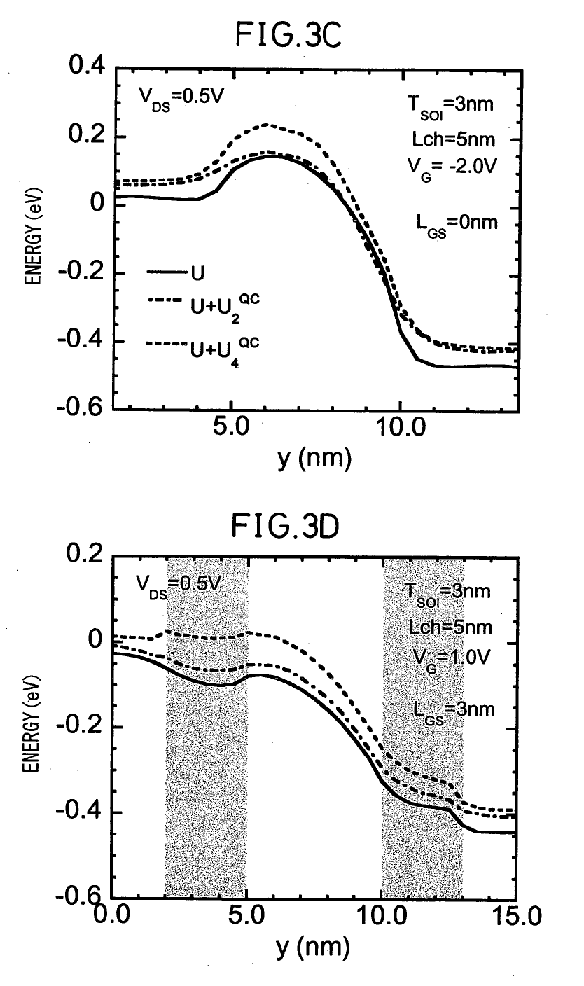

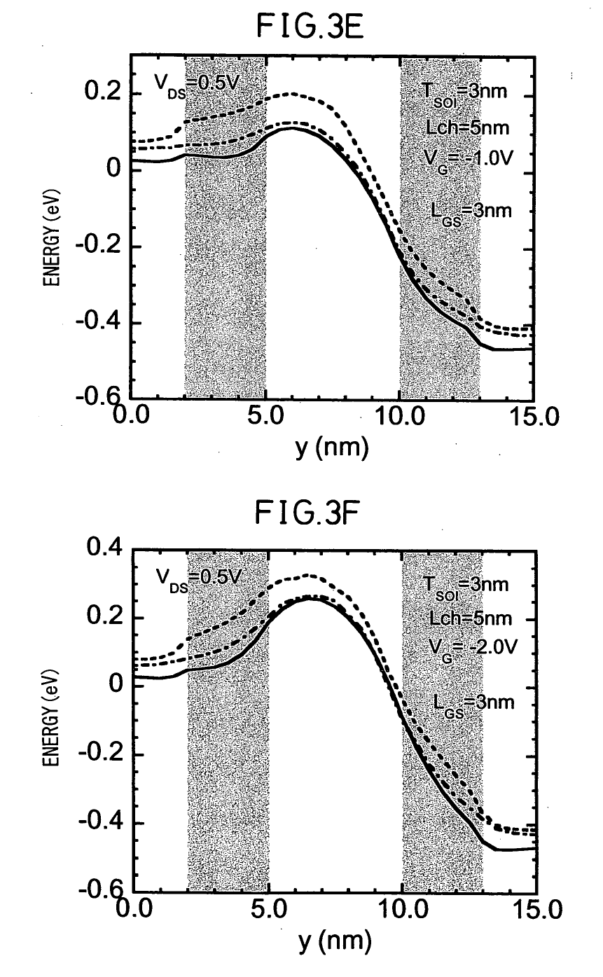

First, a simulation is performed, in which a voltage V_{G} of the gate electrode 8 is changed in a state in which L_{CH} is 5 nm, T_{SOI} is 3 nm and L_{GS} and L_{GD} are 3 nm, respectively, and the drain-source voltage V_{DS} is set to 0.5V in the MOSFET shown in FIG. 1. FIG. 2A to FIG. 2F show the simulation results of the electron sheet density distribution and FIG. 3A to FIG. 3F show the simulation results of the potential distribution. For comparison, the simulation results of the case where the gate electrode 8 overlaps neither the source region 4 nor the drain region 6 are also shown in FIG. 2A to FIG. 2F and FIG. 3A to FIG. 3F, that is, FIG. 2A to FIG. 2C and FIG. 3A to FIG. 3C show the case of no overlap and FIG. 2D to FIG. 2F and FIG. 3D to FIG. 3F show the case of overlap (L_{GS}=L_{GD}=3 nm). FIG. 2A, FIG. 2D, FIG. 3A and FIG. 3D show the case where 1.0 V is applied to the gate electrode, FIG. 2B, FIG. 2E, FIG. 3B and FIG. 3E show the case where −1.0 V is applied to the gate electrode, and FIG. 2C, FIG. 2F, FIG. 3C and FIG. 3F show the case where −2.0 V is applied to the gate electrode. The interval between 5.0 nm and 10.0 nm on the y-axis corresponds to the channel region, the interval equal to or less than 5.0 nm corresponds to the source region, and the interval equal to or more than 10.0 nm corresponds to the drain region.

When a simulation in which the quantum effect has been taken into account is performed, it is necessary to distinguish the electrons belonging to the valleys of two-fold degeneracy from the electrons belonging to the valleys of four-fold degeneracy because their behaviors are different. In each figure, the dashed line denotes the simulation result in the case of the electrons belonging to the valleys of four-fold degeneracy and the alternating long and short dashed line denotes the simulation result in the case of the electrons belonging to the valleys of two-fold degeneracy. The solid line in FIG. 2 denotes the total electron density distribution including both electrons belonging to both the valleys of four-fold degeneracy and electrons belonging to the valleys of two-fold degeneracy. The solid line in FIG. 3 denotes the potential distribution on a classical conduction band.

It is known by the comparison between FIG. 2A and FIG. 2D that when 1.0 V is applied to the gate electrode, the sheet density decreases in the overlap region and increases in the channel region conversely. The reason for this can be thought to be that the three-dimensional electron state changes into the two-dimensional electron state in the overlap region and, therefore, the density of state decreases because the degree of freedom decreases and the sheet density decreases. Due to this, the neutrality condition between donors and charges collapses and a state of excess donors (positive charges) occurs. Because of these excess positive charges, the potential in the overlap region lowers, the potential in the vicinity of the source end of the channel is also lowered as shown in FIG. 3A and FIG. 3D and, moreover, the injection of carrier from the source becomes more likely to occur and the concentration of induced carriers in the channel is increased. This causes the drive current to increase. It is thought that the length of the overlap region needs to be longer than the average interval of the donors (several nm) in order for the state of excess donors to occur in the overlap region.

For the reasons described above, it is thought that the provision of the overlap region can cause the drive current to increase during the on-state.

On the other hand, when a voltage between −1.0 and −2.0 V is applied to the gate electrode, the sheet density distribution in the channel is decreased by providing the overlap region as shown in FIG. 2B and FIG. 2C, and in FIG. 2E and FIG. 2F. This is because, as shown in FIG. 2E and FIG. 2F, the resistance is increased due to the carrier depletion in the overlap region and therefore, the potential energy of the entire area under the gate electrode including the overlap region is increased and the potential barrier formed between the source and the channel during off-state is increased as shown in FIG. 3E and FIG. 3F. Because of this, the leak current during off-state is controlled. Either way, the provision of the overlap region causes the ratio of the on-state current to the off-state current to increase because the on-state current increases and the off-state current decreases.

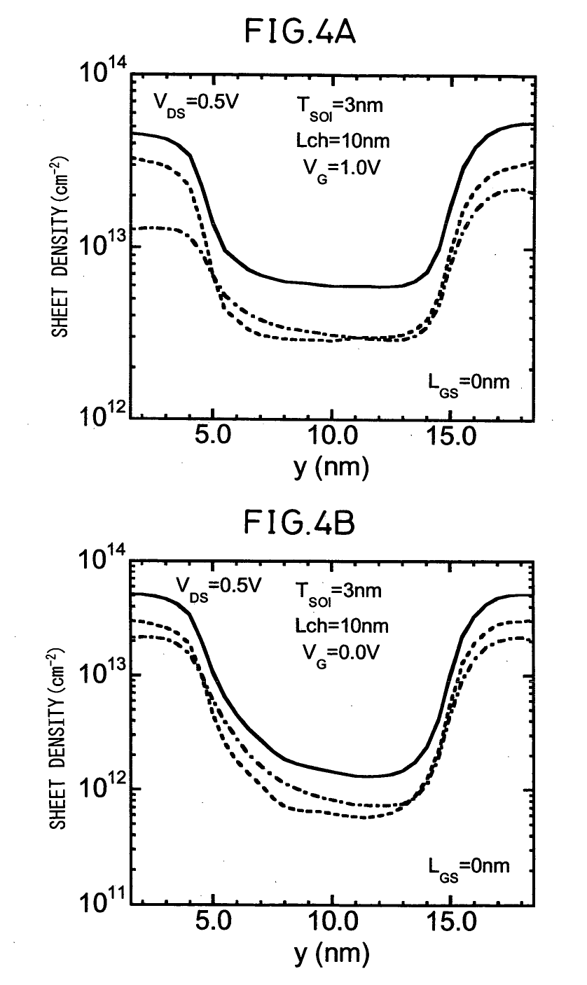

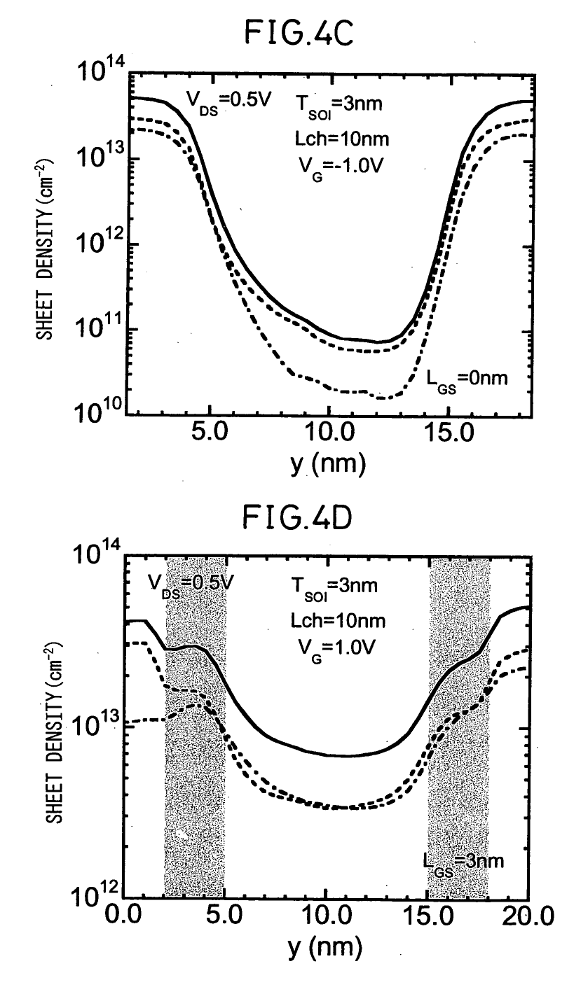

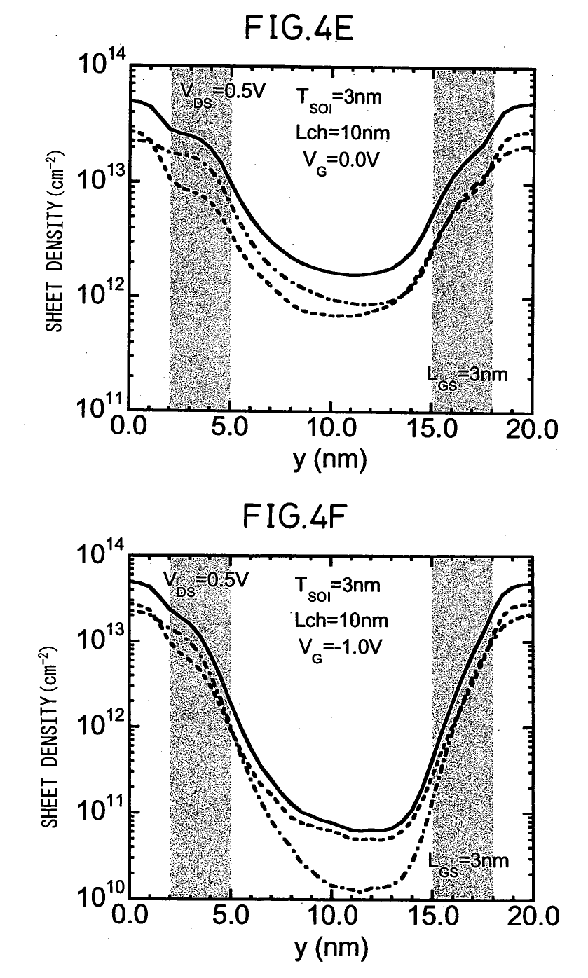

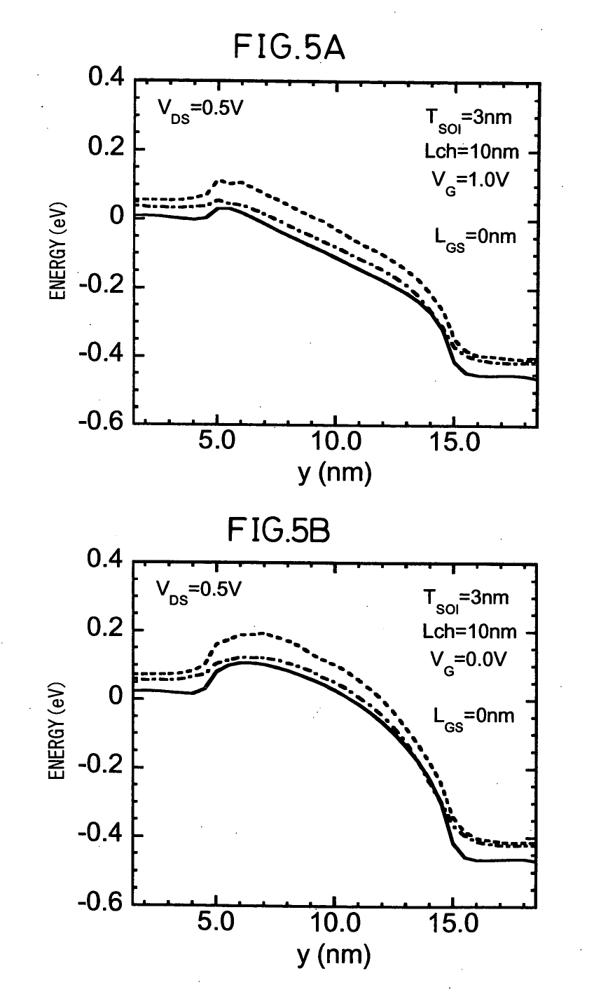

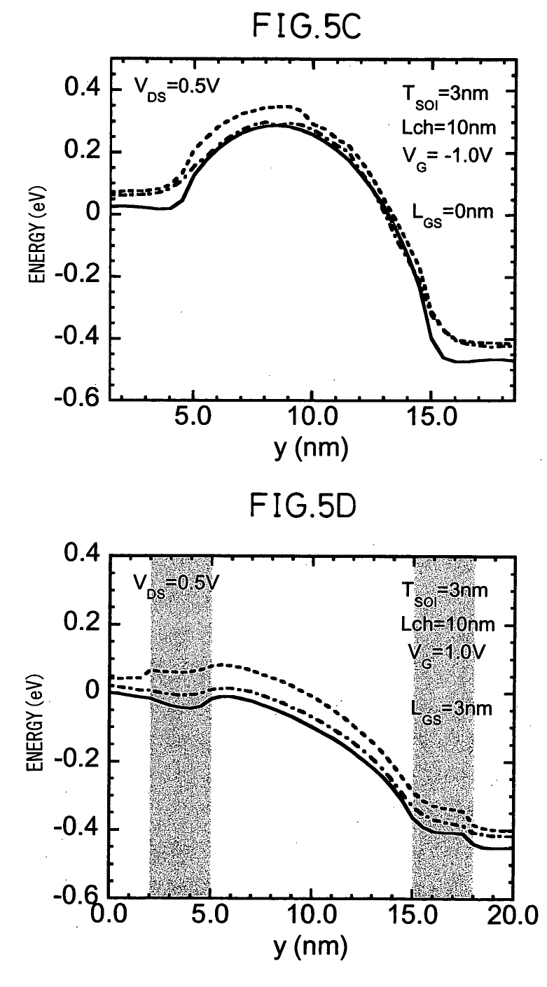

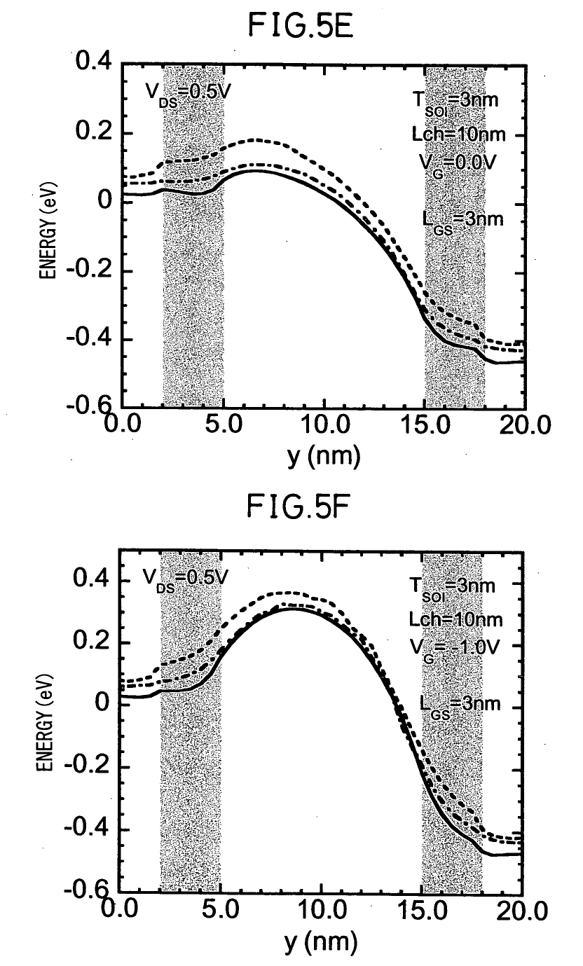

Further, the simulation results of the electron sheet density distribution and the potential distribution, when the channel length L_{CH} is 10 nm, the SOI film thickness T_{SOI} is 3 nm and the overlap length L_{GS} is 3 nm, respectively, are shown in FIG. 4A to FIG. 4F and FIG. 5A to FIG. 5F. FIG. 4A to FIG. 4F and FIG. 5A to FIG. 5F correspond to FIG. 2 and FIG. 3, and FIG. 4A to FIG. 4C and FIG. 5A to FIG. 5C show the case of no overlap and FIG. 4D to FIG. 4F and FIG. 5D to FIG. 5F show the case of overlap (L_{GS}=L_{GD}=3 nm). Furthermore, FIG. 4A and FIG. 4D, and FIG. 5A and FIG. 5D show the case where 1.0 V is applied to the gate electrode, FIG. 4B and FIG. 4E, and FIG. 5B and FIG. 5E show the case where 0.0 V is applied to the gate electrode, and FIG. 4C and FIG. 4F, and FIG. 5C and FIG. 5F show the case where −1.0 V is applied to the gate electrode. The interval between 5.0 nm and 15.0 nm on the y-axis corresponds to the channel region, the interval equal to or less than 5.0 nm corresponds to the source region, and the interval equal to or more than 15.0 nm corresponds to the drain region.

As shown schematically, when L_{CH}=10 nm, the sheet density and potential in the channel exhibit almost the same distribution regardless of the presence or absence of the overlap region. Therefore, when the channel length is equal to or more than 10 nm, the provision of the overlap region does not cause the sub-threshold characteristic to improve considerably.

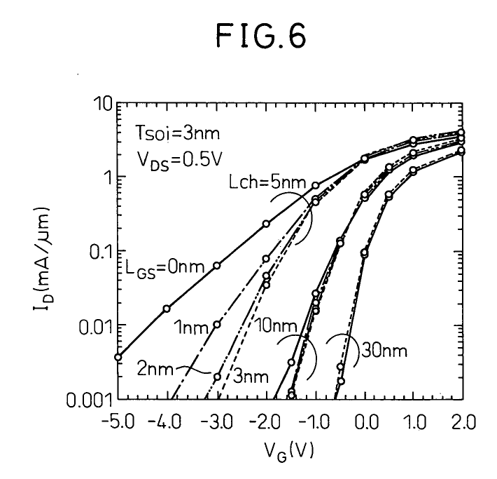

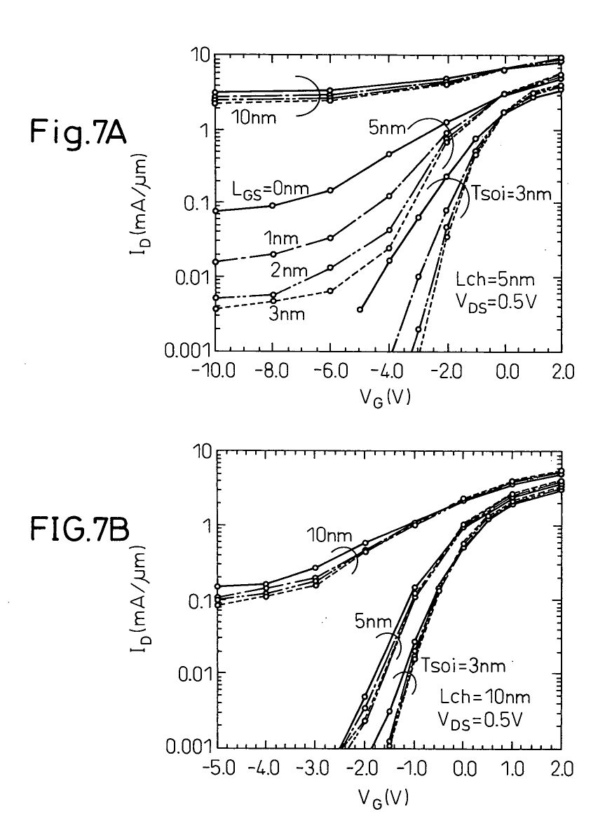

Moreover, another simulation was performed to find the sub-threshold characteristic, in which the channel length L_{CH}, the SOI film thickness T_{SOI} and the overlap lengths L_{GS} and L_{GD} are changed. The results are shown in FIG. 6, FIG. 7A and FIG. 7B. FIG. 6 shows the sub-threshold characteristic of the MOSFET having the structure shown in FIG. 1, when the overlap lengths L_{GS} and L_{GD} are changed to 0 nm, 1 nm, 2 nm and 3 nm in a state in which the SOI film thickness T_{SOI} is set to 3 nm, the drain-source voltage V_{DS} is set to 0.5 V and the channel length L_{CH} is changed to three values, that is, 30 nm, 10 nm and 5 nm.

The steeper the slope of the sub-threshold characteristic is, the higher the ratio of on-state current to off-state current is. As shown in FIG. 6, the sub-threshold characteristic is more degraded as the channel length L_{CH} becomes shorter. When the channel length L_{CH} is 30 nm, it is found that the characteristic is hardly improved even if the overlap region is provided. However, when the channel length L_{CH} is 5 nm, it is found that the sub-threshold characteristic is improved when the overlap region is provided compared to when it is not provided.

FIG. 7A shows the sub-threshold characteristic when the overlap lengths L_{GS} and L_{GD} are changed to 0 nm, 1 nm, 2 nm and 3 nm in a state in which the channel length L_{CH} is fixed to 5 nm, the drain-source voltage V_{DS} is set to 0.5 V, and the SOI film thickness T_{SOI} is changed to three values, that is, 10 nm, 5 nm and 3 nm. From the results, it is found that the thinner the SOI film thickness T_{SOI} becomes, the more the sub-threshold characteristic is improved and when T_{SOI} is equal to or less than 5 nm, the sub-threshold characteristic is improved by the provision of the overlap region.

FIG. 7B shows the sub-threshold characteristic when the overlap lengths L_{GS} and L_{GD} are changed to 0 nm, 1 nm, 2 nm and 3 nm in a state in which the channel length L_{CH} is set to 10 nm, the drain-source voltage V_{DS} is set to 0.5 V and the SOI film thickness T_{SOI} is changed to three values, that is, 10 nm, 5 nm and 3 nm. From the results, it is found that the smaller the SOI film thickness T_{SOI} becomes, the more the sub-threshold characteristic is improved, but when the channel length L_{CH} is 10 nm, the provision of the overlap region does not give much effect to improve the sub-threshold characteristic.

From the simulation results described above, it follows that, although the sub-threshold characteristic is degraded when the channel length is reduced, the degradation of the sub-threshold characteristic can be prevented to a certain extent by setting the SOI film thickness (channel thickness) equal to the channel length or less (a desirable length is 5 nm or less) and providing the overlap region when the channel length is 10 m or less. It is found desirable that the concentration of impurities in the overlap region is equal to or more than the electron density (approximately 10²⁰/cm³) in the inversion layer and the length of the overlap region is equal to or more than 20% of the channel length.

The present invention is also applicable to a new ultra-small MOSFET structure that has been proposed recently and an embodiment is explained below.

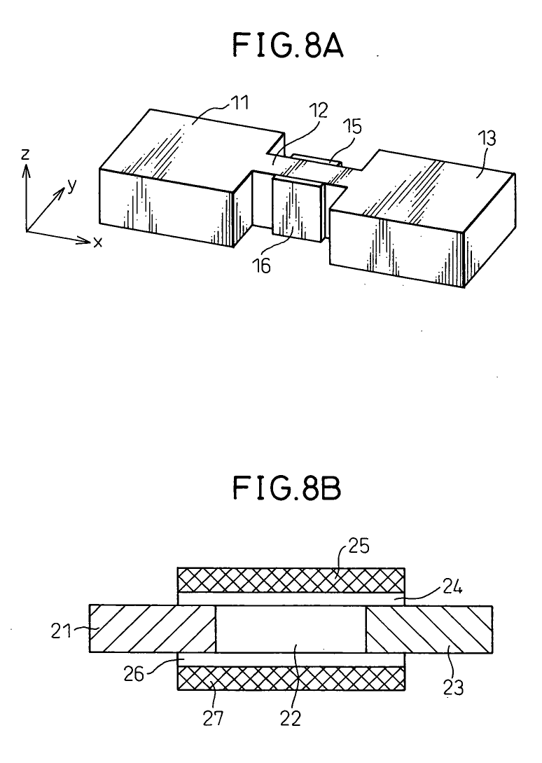

FIG. 8A and FIG. 8B are diagrams showing a MOSFET structure in a second embodiment of the present invention. The MOSFET in the second embodiment has a double-gate structure. As shown in FIG. 8A, a narrow part 12 is formed in the center of a Si body erected on a substrate. The part in the center of the narrow part 12 whose width is 10 nm or less being excluded, both sides of the part and wide parts 11 and 13 are doped with impurities to form a source region and a drain region. The part in the center of the narrow part 12 whose width is 10 nm or less corresponds to a channel region. Then, gate insulating films wider than the channel region are formed at both sides of the channel region and gate electrodes 15 and 16 are further formed thereon.

FIG. 8B shows a diagram showing a sectional view of the gate electrodes 15 and 16 in the x-y plane. As shown schematically, a source region 21 and a drain region 23 are formed at both sides of a channel region 22 of the Si body and further, gate insulating films 24 and 26 are formed on the Si body and gate electrodes 25 and 27 are formed thereon. As shown schematically, the MOSFET in the second embodiment has a structure in which the gate electrodes are provided at both sides of the channel in the MOSFET in the first embodiment shown in FIG. 1. Therefore, this structure is called a double-gate structure.

As shown in FIG. 8B, the gate electrodes 25 and 27 are longer than the channel region 22 and face the source region 21 and the drain region 23 via the gate insulating films 24 and 26, respectively. In other words, the overlap region is formed. Due to this, the same effect as that in the first embodiment can be obtained.

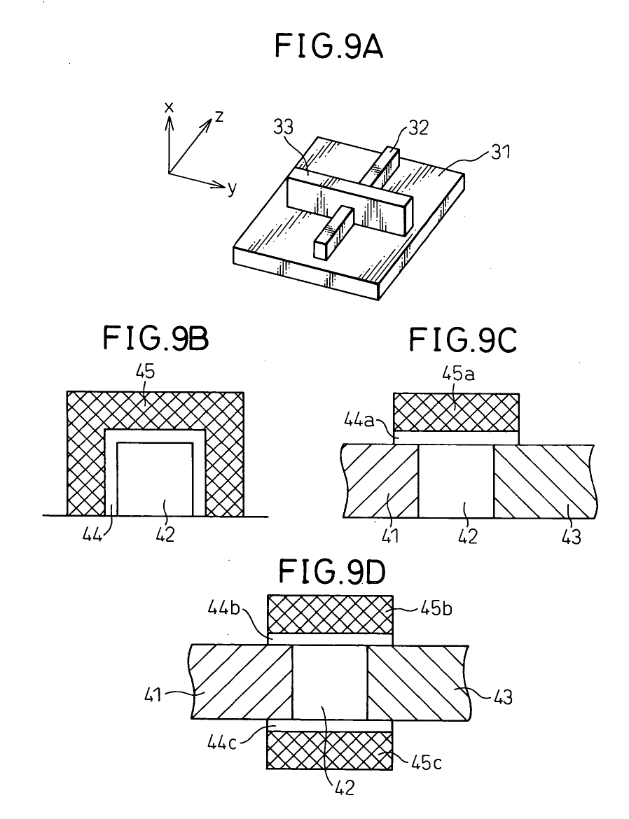

FIG. 9A to FIG. 9D show a MOSFET structure in a third embodiment of the present invention. The MOSFET in the third embodiment has a tri-gate structure (or a Fin structure). As shown in FIG. 9A, a Si body 32 is erected on a substrate 31 and a source region and a drain region are formed at both sides of a channel region. A gate insulating film is formed thereon and a gate electrode 33 is formed so as to sandwich the channel region as shown schematically.

FIG. 9B to FIG. 9D are diagrams showing sectional views of the gate electrode 33, and FIG. 9B is a sectional view in the x-y plane, FIG. 9C is a sectional view in the x-z plane, and FIG. 9D is a sectional view in the y-z plane. As shown in FIG. 9B, a gate electrode 45 is formed around a channel region 42 via a gate insulating film 44 so as to surround the three sides of the channel region 42. Due to this, the structure is called the tri-gate structure. As shown in FIG. 9C and FIG. 9D, a source region 41 and a drain region 43 are formed at both sides of the channel region 42 and further, the gate insulating film 44 (44a to 44c) is formed on a SOI film and the gate electrode 45 (45a to 45c) is formed thereon.

As shown in FIG. 9C and FIG. 9D, the gate electrode (45a to 45c) is longer than the channel region 42 and faces the source region 41 and the drain region 43 via the gate insulating film 44 (44a to 44c). In other words, the overlap region is formed. Due to this, the same effect as that in the first embodiment can be obtained.

As described above, according to the present invention, it is possible to increase the ratio of on-state current to off-state current by preventing, to a certain extent, the degradation of the sub-threshold characteristic due to short-channel effects in the MOSFET whose channel length is 10 nm or less.

We claim:

1. A MOSFET comprising a channel region whose channel length is less than or equal to 10 nm, a source region and a drain region formed at both sides of the channel region, an insulating film provided so as to cover at least the channel region, and a gate electrode provided so as to face the channel region via the insulating film, wherein the length of the gate electrode is greater than the channel length and both ends of the gate electrode overlap the source region and the drain region via the insulating film.

2. The MOSFET as set forth in claim 1, wherein the thickness of the SOI film is less than or equal to the channel length.

3. The MOSFET as set forth in claim 2, wherein the channel region, the source region and the drain region are formed on a silicon-on-insulator (SOI) film.

4. The MOSFET as set forth in claim 1, wherein the respective lengths across which the gate electrode overlaps the source region and the drain region via the insulating film are greater than or equal to 20% of the channel length.

5. The MOSFET as set forth in claim 2, wherein the respective lengths across which the gate electrode overlaps the source region and the drain region via the insulating film are greater than or equal to 20% of the channel length.

6. The MOSFET as set forth in claim 3, wherein the respective lengths across which the gate electrode overlaps the source region and the drain region via the insulating film are greater than or equal to 20% of the channel length.

7. The MOSFET as set forth in claim 1, wherein the channel region is substantially a silicon layer that does not contain impurities.

8. The MOSFET as set forth in claim 2, wherein the channel region is substantially a silicon layer that does not contain impurities.

9. The MOSFET in claim 3, wherein the channel region is substantially a silicon layer that does not contain impurities.

10. The MOSFET in claim 4, wherein the channel region is substantially a silicon layer that does not contain impurities.

11. The MOSFET in claim 5, wherein the channel region is substantially a silicon layer that does not contain impurities.

12. The MOSFET in claim 6, wherein the channel region is substantially a silicon layer that does not contain impurities.

13. The MOSFET as set forth in claim 1, wherein the concentration of impurities in the source region and drain region overlapping the gate electrode via the insulating film is greater than or equal to 10²⁰/cm³.

14. The MOSFET as set forth in claim 2, wherein the concentration of impurities in the source region and drain region overlapping the gate electrode via the insulating film is greater than or equal to 10²⁰/cm³.

15. The MOSFET in claim 3, wherein the concentration of impurities in the source region and drain region overlapping the gate electrode via the insulating film is greater than or equal to 10²⁰/cm³.

16. The MOSFET in claim 4, wherein the concentration of impurities in the source region and drain region overlapping the gate electrode via the insulating film is greater than or equal to 10²⁰/cm³.

17. The MOSFET in claim 7, wherein the concentration of impurities in the source region and drain region overlapping the gate electrode via the insulating film is greater than or equal to 10²⁰/cm³.

18. The MOSFET in claim 12, wherein the concentration of impurities in the source region and drain region overlapping the gate electrode via the insulating film is greater than or equal to 10²⁰/cm³.

19. The MOSFET in claim 13, wherein the concentration of impurities in the source region and drain region overlapping the gate electrode via the insulating film is greater than or equal to 10²⁰/cm³.
